(19) United States
(12) Patent Application Publication
(10) Pub. No.: US 2017/0163571 A1
(43) Pub. Date: Jun. 8, 2017

(54) METHOD AND APPARATUS FOR SUPRESSING ELECTROMAGNETIC INTERFERENCE

(71) Applicants: Le Holdings (Beijing) Co., Ltd., Beijing (CN); LE SHI ZHI XIN ELECTRONIC TECHNOLOGY (TIANJIN) LIMITED, Beijing (CN)

(72) Inventor: Xiaoming HOU, Tianjin (CN)

(21) Appl. No.: 15/250,529

(22) Filed: Aug. 29, 2016

Related U.S. Application Data
(63) Continuation of application No. PCT/CN2016/088522, filed on Jul. 5, 2016.

(30) Foreign Application Priority Data
Dec. 8, 2015 (CN) 201510897640.1

(51) Int. Cl. H04L 12/935; H04L 12/931; H04L 25/08; H03H 7/42

(52) U.S. Cl. CPC H04L 49/30; H03H 7/427; H04L 49/405; H04L 25/08

(57) ABSTRACT

A method and an apparatus for suppressing electromagnetic interference are disclosed. The method includes: receiving a signal from an IC end and performing common-mode suppression processing on the received signal, to at least eliminate or mitigate an interference signal mixed in the received signal and performing coupling processing on the signal on which common-mode suppression processing has been performed, to at least obtain a signal having an enhanced driving capability, and sending the signal to a network interface end. According to embodiments of the present disclosure, because first a signal from an IC end is received and common-mode suppression processing is performed on the received signal, at least an interference signal is eliminated or mitigated in advance; next, coupling processing is then performed on the signal on which common-mode suppression processing has been performed, to at least obtain a signal having an enhanced driving capability, and the signal is sent to the network interface end.

### CROSS-REFERENCE TO RELATED APPLICATIONS

This application is a continuation of PCT Application No. PCT/CN2016/088522 filed on Jul. 5, 2016, and is based upon and claims priority to Chinese Patent Application No. 2015108976401, filed before Chinese Patent Office on Dec. 8, 2015 and entitled “METHOD AND APPARATUS FOR SUPPRESSING ELECTROMAGNETIC INTERFERENCE”, the entire contents of which are incorporated herein by reference.

### TECHNICAL FIELD

The present disclosure relates to the technical field of electrical data processing, and more particularly, to a method and an apparatus for suppressing electromagnetic interference.

### BACKGROUND

A network transformer (which may be simply referred to as a data pump) is an essential device on a consumer-grade PCI network interface card, and may also be referred to as a network isolation transformer. As compared with a common transformer, the network transformer uses a different frequency, and therefore uses a different magnetically-conductive material. The common transformer is mainly used to transmit energy, whereas the network transformer is usually used to transmit a signal.

Specifically, the network transformer mainly has two functions: One function is to transmit data, where the network transformer uses a coil to perform coupled filtering on a differential signal transferred from a physical layer (PHY) to enhance the signal, and performs conversion to couple the signal to another end of a connected networking cable having a different level. The other function is to isolate different levels among different network devices connected through networking cables, to prevent different voltages from being transmitted on a networking cable to damage a device.

The network transformer mainly includes a coupled transformer and a common-mode filter. The coupled transformer is located at an IC end, and the common-mode filter is located at a network interface end. A signal from the IC end is first processed by the coupled transformer to enhance the signal, and the common-mode filter is then used to filter out an interference signal. However, in a process of implementing the present disclosure by the inventor, the inventor finds that because the interference signal is generated by the IC end, the coupled transformer cannot eliminate the interference signal, but instead, after passing through the coupled transformer, the interference signal has an increased driving capability, and interference is in fact increased. In this case, when the interference signal passes through the common-mode filter, it is very difficult or even impossible to eliminate interference, resulting that a phenomenon of excessive electromagnetic interference (EMI for short) often occurs.

### SUMMARY

One of the objectives of the present disclosure is to provide a method and an apparatus for suppressing electromagnetic interference, which are used to resolve a problem in the related art that it is very difficult or even impossible for a network transformer to eliminate an interference signal, thereby achieving an objective of suppressing or mitigating EMI.

Technical solutions used in embodiments of the present disclosure are as follows:

According to a first aspect, an embodiment of the present disclosure provides a method for suppressing electromagnetic interference, applied to a transformer, and including:

receiving a signal from an IC end and performing common-mode suppression processing on the received signal, to at least eliminate or mitigate an interference signal mixed in the received signal; and

performing coupling processing on the signal on which common-mode suppression processing has been performed, to at least obtain a signal having an enhanced driving capability, and sending the signal to a network interface end.

According to a second aspect, an embodiment of the present disclosure further provides an apparatus for suppressing electromagnetic interference, including:

a first circuit, configured to receive a signal from an IC end and perform common-mode suppression processing on the received signal, to at least eliminate or mitigate an interference signal mixed in the received signal; and

a second circuit, configured to perform coupling processing on the signal on which common-mode suppression processing has been performed, to at least obtain a signal having an enhanced driving capability, and send the signal to a network interface end.

### BRIEF DESCRIPTION OF THE DRAWINGS

One or more embodiments are exemplarily described by using a diagram that corresponds to the one or more embodiments in the accompanying drawings. These exemplary descriptions do not constitute any limitation on the embodiments. Elements that have the same reference numerals in the accompanying drawings are represented as similar elements. Unless specifically indicated, the diagrams in the accompanying drawings do not constitute any limitations on proportions.

FIG. 1 is a schematic flowchart illustrating a method for suppressing electromagnetic interference according to some embodiments of the present disclosure;

FIG. 2 is a schematic flowchart illustrating a method for suppressing electromagnetic interference according to some embodiments of the present disclosure;

FIG. 3 is a schematic flowchart illustrating a method for suppressing electromagnetic interference according to some embodiments of the present disclosure;

FIG. 4 is a schematic structural diagram illustrating an apparatus for suppressing electromagnetic interference according to some embodiments of the present disclosure;

FIG. 5 is a schematic structural diagram illustrating an apparatus for suppressing electromagnetic interference according to some embodiments of the present disclosure; and

FIG. 6 is a schematic structural diagram illustrating an apparatus for suppressing electromagnetic interference according to some embodiments of the present disclosure.

### DETAILED DESCRIPTION

To make the objectives, technical solutions, and advantages of the present disclosure more clearly, the following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by persons of ordinary skill in the art based on the embodiments of the present disclosure without creative efforts shall fall within the protection scope of the present disclosure.

FIG. 1 is a schematic flowchart illustrating a method for suppressing electromagnetic interference according to Embodiment 1 of the present disclosure. As illustrated in FIG. 1, the method may include at least the following steps:

S101: A signal is received from an IC end and common-mode suppression processing is performed on the received signal, to at least eliminate or mitigate an interference signal mixed in the received signal.

In this embodiment, the signal from the IC end may include, but is not limited to, a differential signal. The differential signal may be decomposed into a common-mode signal and a differential-mode signal. The common-mode signal is a same signal that acts on two input ends of a differential amplifier or an instrumentation amplifier, is usually generated because of line conduction, spatial magnetic field interference, and the like, and is an undesired signal.

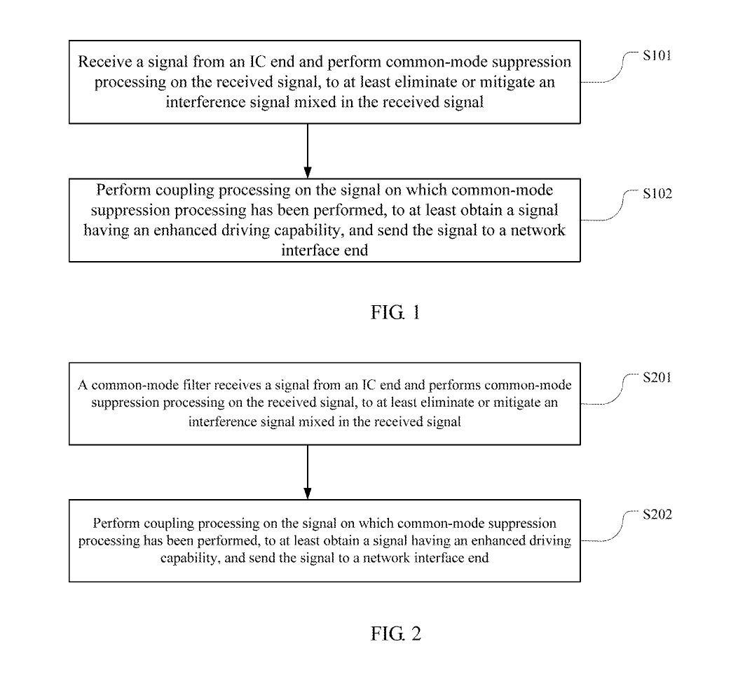

During common-mode suppression processing, a specific common-mode filter may be used. The common-mode filter may include at least a common-mode inductor. For details, reference may be made to the following FIG. 2 and related description of FIG. 2, and details are no longer described herein.

It should be noted that the common-mode filter is not the only optional solution for implementing an embodiment of the present disclosure, and another alternate technology measure may also be used.

S102: Coupling processing is performed on the signal on which common-mode suppression processing has been performed, to at least obtain a signal having an enhanced driving capability, and the signal is sent to a network interface end.

In this embodiment, in the signal on which common-mode suppression processing has been performed, an interference signal that is generated because of line conduction, spatial magnetic field interference, and the like is eliminated or suppressed. Herein, when coupling processing is performed on the signal on which common-mode suppression processing has been performed, amplification of an interference signal is avoided to the greatest extent.

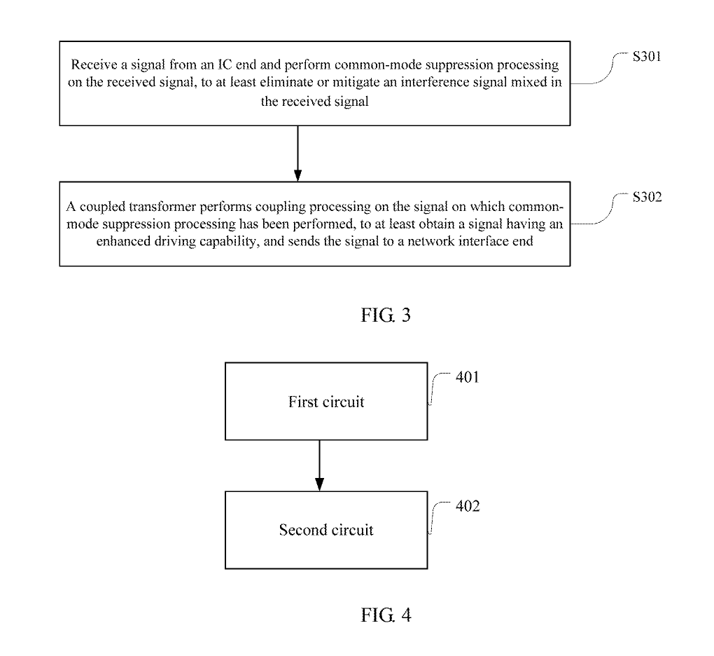

During the coupling processing, a specific coupled transformer may be used to amplify a signal. The specific coupled transformer may include at least one differential-mode couple coil. For details, reference is made to the following FIG. 3 and related description of FIG. 3, and details are no longer described herein. A specific type of the coupled transformer may be flexibly chosen according to a use requirement, for example, a fully-coupled transformer or a loosely-coupled transformer may be chosen.

FIG. 2 is a schematic flowchart illustrating a method for suppressing electromagnetic interference according to Embodiment 2 of the present disclosure. As illustrated in FIG. 2, the method may include at least the following steps:

S201: A common-mode filter receives a signal from an IC end and performs common-mode suppression processing on the received signal, to at least eliminate or mitigate an interference signal mixed in the received signal.

The common-mode filter includes a common-mode inductor. The common-mode inductor is substantially a bidirectional filter: In one aspect, common-mode electromagnetic interference in a signal line needs to be filtered. In another aspect, the common-mode inductor needs to be suppressed from generating electromagnetic interference, thereby avoiding influence on normal work of another electronic device in a same electromagnetic environment.

The common-mode inductor includes two common-mode inductor coils. The two coils are wound on a same iron core, and have a same quantity of turns and a same phase (reverse winding). In this way, when a normal current in a circuit flows through the common-mode inductor, the current generates reverse magnetic fields in inductor coils that have a same-phase winding, so that the magnetic fields cancel each other. In this case, a common signal current is mainly affected by resistance of the coils (and a low damping effect caused by leakage inductance). When a common-mode current flows through the coils, because of isotropy of the common-mode current, a same-direction magnetic field may be generated in the coils to increase inductance of the coils, making the coils have high impedance, to generate a relatively strong damping effect. Therefore, the common-mode current is attenuated, thereby achieving an objective of filtering.

It should be noted that, in this embodiment, during fabrication of the common-mode inductor, reference is made to the following requirements:

1) Wires wound on a magnetic core of a coil need to be insulated from each other, to ensure that a breakdown short circuit does not occur between turns of coils under an effect of a transient overvoltage.

2) When a transient high current flows through a coil, it is ensured that a magnetic core is not saturated.

3) A magnetic core in a coil should be insulated from the coil, to prevent a breakdown between the magnetic core and the coil under an effect of a transient overvoltage.

4) A coil should better be wound in a single layer. In this way, parasitic capacitance of the coil can be reduced, thereby enhancing a capability of withstanding a transient overvoltage of the coil.

For example, for a current-driven type IC, a two-wire common-mode inductor is used in combination with an auto-transformer, or a three-wire common-mode inductor may be used, as long as a cost of two magnetic cores is reduced.

Specifically, the foregoing common-mode filter may be a five-end device, and includes two input ends, two output ends, and one ground end. During use, the housing should be connected to ground. The circuit specifically includes a common-mode inductor (also referred to as a common-mode choke coil) L and filtering capacitors C1 to C4. L does not act on series-mode interference. However, when common-mode interference occurs, because two coils have a same magnetic flux direction, after coupling, a total inductance increases rapidly. Therefore, L presents large inductance to a common-mode signal, making it difficult for the common-mode signal to pass through, so that L is referred to as a common-mode choke coil or a common-mode inductor.

In a specific process of implementing this embodiment, a miniature common-mode inductor based on a high-frequency interference suppression strategy may be used. A signal of the common-mode inductor is not attenuated, and the common-mode inductor has a small volume, is convenient to use, and has advantages such as desirable balance, convenient use, and high quality. Ferrite may be used for a magnetic core, and two wires are wound, so that a high common-mode interference signal and a low differential-mode interference signal can be suppressed at the same time. The low differential-mode interference signal suppresses an interference source, and can hardly deform in a high-speed signal. Therefore, advantages such as a small volume, desirable balance, convenient use, and high quality are achieved.

In step S201 according to this embodiment, that a common-mode filter formed of a common-mode inductor receives a signal from an IC end and performs common-mode suppression processing on the received signal may further specifically include that: the common-mode inductor has a center tap, and the center tap of the common-mode inductor is connected to a power supply or ground according to a driving type of an IC end chip. Specifically, that the center tap of the common-mode inductor is connected to a power supply or ground includes that: if the driving type of the IC end chip is voltage driven, the center tap of the common-mode inductor is connected to the power supply; or if the driving type of the IC end chip is current driven, the center tap of the common-mode inductor is connected to ground by using a capacitor.

S202: Coupling processing is performed on the signal on which common-mode suppression processing has been performed, to at least obtain a signal having an enhanced driving capability, and the signal is sent to a network interface end.

In this embodiment, in the differential signal on which the common-mode filter processing is performed, a common-mode interference signal generated because of line conduction, spatial magnetic field interference, and the like is eliminated or suppressed. Herein, when the coupling processing is performed on the differential signal on which common-mode suppression processing is performed, amplification of a common-mode interference signal is avoided to the greatest extent.

During the coupling processing, a specific coupled transformer may be used to amplify a signal. The specific coupled transformer may include at least one differential-mode couple coil. For details, reference is made to the following FIG. 3 and related description of FIG. 3, and details are no longer described herein. A specific type of the coupled transformer may be flexibly chosen according to a use requirement, for example, a fully-coupled transformer or a loosely-coupled transformer may be chosen. The coupled transformer has both a function of protecting an internal circuit and a technical effect of isolating a high current direct-current signal. As informed of this embodiment of the present disclosure, a person skilled in the art may perform implementation without creative efforts, and details are no longer described herein.

FIG. 3 is a schematic flowchart illustrating a method for suppressing electromagnetic interference according to Embodiment 3 of the present disclosure. As illustrated in FIG. 3, the method may include at least the following steps:

S301: A signal is received from an IC end and common-mode suppression processing is performed on the received signal, to at least eliminate or mitigate an interference signal mixed in the received signal.

In this embodiment, for detailed description of this step, reference may be made to related description of Embodiments 1 and 2 above, and details are no longer described herein.

S302: A coupled transformer performs coupling processing on the signal on which common-mode suppression processing has been performed, to at least obtain a signal having an enhanced driving capability, and sends the signal to a network interface end.

In this embodiment, step S302 may include that: the coupled transformer has a center tap, and the center tap of the coupled transformer is connected to a power supply or ground according to a driving type of an IC end chip.

Specifically, that the center tap of the coupled transformer is connected to a power supply or ground according to a driving type of an IC end chip includes: if the driving type of the IC end chip is voltage driven, the center tap of the coupled transformer is connected to the power supply, specifically, is connected to the power supply by using a pull-up resistor; or if the driving type of the IC end chip is current driven, the center tap of the coupled transformer is connected to ground, specifically, may be connected to ground by using a capacitor.

In this embodiment, when the driving type of the IC end chip is voltage driven, and the center tap of the coupled transformer is connected to the power supply, the center tap of the coupled transformer may be connected to a power supply having a matching level according to a value of a driving voltage required to drive the IC end chip. A voltage value of the power supply is determined according to a chip, and may be 3.3 V, 2.5 V, 1.8 V, and the like.

In this embodiment, the coupled transformer performs the coupling processing. Reference may be made to related description of the related art, and details are no longer described herein.

FIG. 4 is a schematic structural diagram illustrating an apparatus for suppressing electromagnetic interference according to Embodiment 4 of the present disclosure. As illustrated in FIG. 4, the apparatus may include at least the following hardware modules: a first circuit 401 and a second circuit 402 that are electrically connected to each other and can perform data communication with each other. Specifically:

The first circuit 401 is configured to receive a signal from an IC end and perform common-mode suppression processing on the received signal, to at least eliminate or mitigate an interference signal mixed in the received signal.

The second circuit 402 is configured to perform coupling processing on the signal on which common-mode suppression processing has been performed, to at least obtain a signal having an enhanced driving capability, and send the signal to a network interface end.

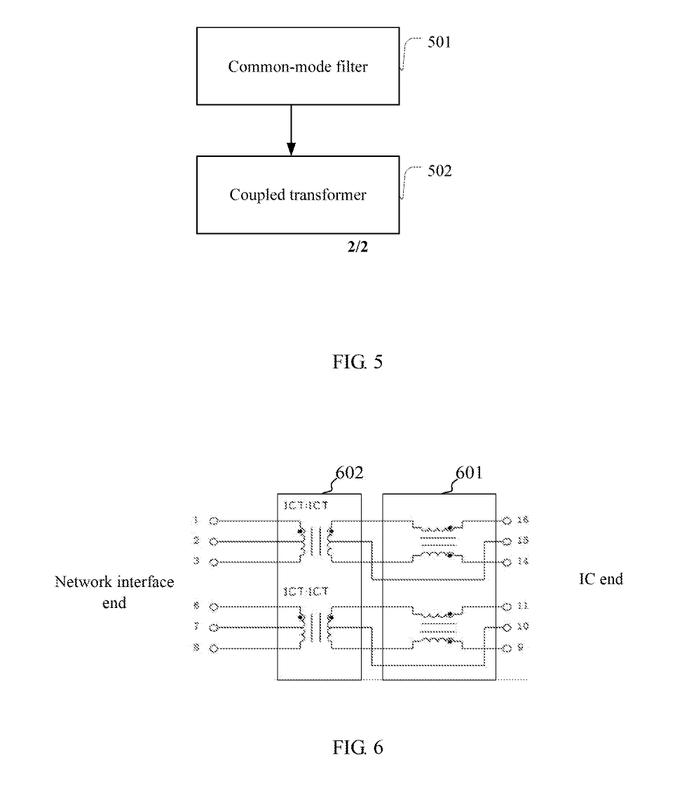

FIG. 5 is a schematic structural diagram illustrating an apparatus for suppressing electromagnetic interference according to Embodiment 5 of the present disclosure. As illustrated in FIG. 5, the apparatus may include at least the following hardware modules: a common-mode filter 501 and a coupled transformer 502 that are electrically connected to each other and can perform data communication with each other. The common-mode filter 501 is configured to receive a signal from an IC end and perform common-mode suppression processing on the received signal, to at least eliminate or mitigate an interference signal mixed in the received signal. The coupled transformer 502 is configured to perform coupling processing on the signal on which common-mode suppression processing has been performed, to at least obtain a signal having an enhanced driving capability, and send the signal to a network interface end.

In some necessary scenario requirements, peripheral circuits may be further configured for the apparatus in the embodiments in FIG. 4 and FIG. 5 above. For example, a Bob Smith circuit may be configured when a two-wire common-mode inductor is used and a driving type of an IC is current driven. This circuit has two functions: One function is to provide impedance matching between any two pairs of differential signals of a network interface. The other function is that the circuit may provide a return path for a common-mode signal.

FIG. 6 is a schematic structural diagram illustrating an apparatus for suppressing electromagnetic interference according to Embodiment 6 of the present disclosure. As illustrated in FIG. 6, the apparatus may include at least the following hardware modules: a common-mode filter 601 and a coupled transformer 602 that are connected to each other and that can perform data communication with each other. Technical effects and details of the modules are no longer described herein, and are comprehensible with the information provided in the foregoing embodiments of the present disclosure or by the related art, and details are no longer described herein.

Herein, only a flow of a signal during processing by using the apparatus in this embodiment is briefly described: An original differential signal from an IC end is input from 4 pins personal identification number (PIN) 9/11/14/16 of a common-mode filter, flows through a common-mode inductor of the common-mode filter 601 and the coupled transformer 602, is output from 4 pins PIN 1\3\6\8 of the coupled transformer 602, and is output to a network interface end.

The PIN 9/11/14/16 is an input end of the signal, the PIN 1\3\6\8 is an output end of the signal, and the PIN 10\15\2\7 is a center tap and can be connected to ground or a power supply.

In the foregoing embodiment, a chip of the IC end includes, but is not limited to, a PHY chip.

It should be noted that, during actual disclosure of an embodiment of the present disclosure, multiple groups of the common-mode filter 601 and the coupled transformer 602 may be included, to satisfy specific requirements for suppression of electromagnetic interference, amplification of a signal, and the like.

The described apparatus embodiment is merely exemplary. The modules described as separate parts may or may not be physically separated, and parts shown as modules may or may not be physical modules, which may be located in one position, or may be distributed on multiple network modules. A part of or all of the modules may be selected according to actual needs to achieve the objectives of the solutions of the embodiments. Persons of ordinary skill in the art may understand and implement the embodiments without creative efforts.

As can be known from the description of the foregoing implementation manners, persons skilled in the art may clearly understand that the implementation manners may be implemented by using software plus a necessary universal hardware platform or may certainly be implemented by using hardware.

Finally, it should be noted that the foregoing embodiments are merely intended for describing the technical solutions of the present disclosure rather than limiting the present disclosure. Although the present disclosure is described in detail with reference to the foregoing embodiments, persons of ordinary skill in the art should understand that they may still make modifications to the technical solutions described in the foregoing embodiments or make equivalent replacements to some technical features thereof, without departing from the spirit and scope of the technical solutions of the embodiments of the present disclosure.

What is claimed is

1. A method for suppressing electromagnetic interference, applied to transformer, and comprising:
receiving a signal from an IC end and performing common-mode suppression processing on the received signal, to at least eliminate or mitigate an interference signal mixed in the received signal; and
performing coupling processing on the signal on which common-mode suppression processing has been performed, to at least obtain a signal having an enhanced driving capability, and sending the signal to a network interface end.

2. The method according to claim 1, wherein the receiving a signal from an IC end and performing common-mode suppression processing on the received signal comprises: receiving, by a common-mode filter, the signal from the IC end and performing common-mode suppression processing on the received signal, to at least eliminate or mitigate the interference signal mixed in the received signal.

3. The method according to claim 1, wherein the common-mode filter has a center tap, and the center tap of the common-mode filter is connected to a power supply or ground according to a driving type of an IC end chip.

4. The method according to claim 3, wherein that the center tap of the common-mode filter is connected to a power supply or ground comprises: if the driving type of the IC end chip is voltage driven, the center tap of the common-mode filter is connected to the power supply: or if the driving type of the IC end chip is current driven, the center tap of the common-mode filter is connected to ground.

5. The method according to claim 1, wherein the performing coupling processing on the signal on which common-mode suppression processing has been performed comprises: performing, by a coupled transformer, coupling processing on the signal on which common-mode suppression processing has been performed, to at least obtain a signal having an enhanced driving capability, and sending the signal to the network interface end.

6. The method according to claim 5, wherein the coupled transformer has a center tap, and the center tap of the coupled transformer is connected to a power supply or ground according to a driving type of an IC end chip.

7. The method according to claim 6, wherein that the center tap of the coupled transformer is connected to a power supply or ground according to a driving type of an IC end chip comprises: if the driving type of the IC end chip is voltage driven, the center tap of the coupled transformer is connected to the power supply; or if the driving type of the IC end chip is current driven, the center tap of the coupled transformer is connected to ground.

8. The method according to claim 7, wherein that if the driving type of the IC end chip is voltage driven, the center tap of the coupled transformer is connected to the power supply comprises: according to a value of a driving voltage required to drive the IC end chip, the center tap of the coupled transformer is connected to a power supply having a matching level.

9. An apparatus for suppressing electromagnetic interference, comprising:
a first circuit, configured to receive a signal from an IC end and perform common-mode suppression processing on the received signal, to at least eliminate or mitigate an interference signal mixed in the received signal; and
a second circuit, configured to perform coupling processing on the signal on which common-mode suppression processing has been performed to at least obtain a signal having an enhanced driving capability, and send the signal to a network interface end.

10. The apparatus according to claim 9, wherein the first circuit comprises a common-mode filter, and the second circuit comprises a coupled transformer.
